(19) United States
(12) Patent Application Publication
(10) Pub. No.: US 2026/0271228 A1
(43) Pub. Date: Sep. 10, 2026

(54) LIQUID COOLING DEVICE WITH A WATER BLOCK

(71) Applicant: COOLER MASTER CO., LTD., Taipei City (TW)

(72) Inventors: Jen-Chih CHENG, Taipei City (TW); Shui-Fa TSAI, Taipei City (TW)

(73) Assignee: COOLER MASTER CO., LTD., Taipei City (TW)

(21) Appl. No.: 19/465,502

(22) Filed: Jan. 30, 2026

(30) Foreign Application Priority Data
Mar. 5, 2025 (TW) 114108166

(51) Int. Cl. H05K 7/20

(52) U.S. Cl. CPC H05K 7/20272; H05K 7/20309; H05K 7/20318

(57) ABSTRACT

A water block includes a main body and a heat transfer assembly. The heat transfer assembly includes a condensation plate coupled with the main body. The condensation plate has a condensation flow channel. The heat transfer assembly also includes a heat-absorbing plate that is coupled with one side of the condensation plate facing away the main body. The heat-absorbing plate has an evaporation flow channel. The heat transfer assembly further includes a flow guide plate that is disposed between the condensation plate and the heat-absorbing plate. The flow guide plate has a plurality of communication holes, and the evaporation flow channel is in fluid communication with the condensation flow channel via the communication holes.

### CROSS-REFERENCE TO RELATED APPLICATIONS

This application claims priority to Taiwan Application No. 114108166, filed on Mar. 5, 2025, which is incorporated herein by reference in its entirety.

### TECHNICAL FIELD

The present invention relates to a water block, and more particularly to a water block used for liquid cooling device.

### BACKGROUND

Conventional water blocks typically include a copper base that is thermally coupled to a heat source, allowing heat generated by the heat source to be transferred to the water block. A cooling fluid flows through the water block, exchanging heat with the water block to remove the heat therefrom. However, in such configurations, thermal coupling through the copper base may cause heat to be concentrated in a specific region of the copper base, hindering uniform heat conduction throughout the entire copper base. As a result, the overall heat dissipation efficiency of the water block may be compromised. Accordingly, there is a need in the art for improved water block structures that address the aforementioned concerns .

### SUMMARY

In general terms, this disclosure is directed to a liquid cooling device having a water block. In some embodiment, and by non-limiting example, the present disclosure provides a water block having a structural configuration that improves heat dissipation efficiency.

One aspect of the present disclosure provides a water block for a liquid cooling device. The water block includes a main body and a heat transfer assembly. The heat transfer assembly includes a condensation plate coupled with the main body. The condensation plate has a condensation flow channel. The heat transfer assembly also includes a heat-absorbing plate coupled with one side of the condensation plate facing away from the main body. The heat-absorbing plate has an evaporation flow channel. The heat transfer assembly further includes a flow guide plate disposed between the condensation plate and the heat-absorbing plate. The flow guide plate has a plurality of communication holes. The evaporation flow channel is in fluid communication with the condensation flow channel through the communication holes.

In some embodiments, the condensation flow channel is serpentine.

In some embodiments, the evaporation flow channel is serpentine.

In some embodiments, the condensation flow channel includes a plurality of first linear segments and a plurality of first turning segments, and the evaporation flow channel includes a plurality of second linear segments and a plurality of second turning segments. In some embodiments, the first linear segments are parallel and spaced apart from one another and successively interconnected by a corresponding first turning segment. In some embodiments, the second linear segments are parallel and spaced apart from one another and successively interconnected by a corresponding second turning segment. In some embodiments, the first linear segments are aligned with the second linear segments. In some embodiments, the communication holes are arranged in two parallel rows on opposite sides of the flow guide plate. In some embodiments, the communication holes connect the first turning segments to the second turning segments.

In some embodiments, the condensation plate and the main body together define a heat exchange chamber, the condensation plate having an inner surface, an outer surface opposite to the inner surface, and a plurality of fin structures protruding from the inner surface, the condensation flow channel being recessed from the outer surface.

In some embodiments, the evaporation flow channel, the communication holes, and the condensation flow channel collectively form a closed flow path containing a working fluid that undergoes phase changes between liquid and vapor states.

In some embodiments, the condensation plate and the heat-absorbing plate are coupled together along a peripheral region to define a closed internal flow space for circulation of a working fluid.

Another aspect of the present disclosure provides a water block for a cooling device. The water block includes a main body, and a heat transfer assembly. The heat transfer assembly includes a condensation plate coupled with the main body. The condensation plate has a plurality of linear condensation flow channels. The condensation flow channels are parallel and spaced apart. The heat transfer assembly further includes a heat-absorbing plate coupled with one side of the condensation plate facing away the main body. The heat-absorbing plate has a plurality of linear evaporation flow channels. The evaporation flow channels are parallel and spaced apart and the evaporation flow channels are in fluid communication with the condensation flow channels.

In some embodiments, the condensation flow channels and the evaporation flow channels are interleaved.

In some embodiments, the heat-absorbing plate further comprises a plurality of communication grooves located at opposite ends of the evaporation flow channels, the evaporation flow channels being in fluid communication with the condensation flow channels via the communication grooves. In some embodiments, the evaporation flow channels and the condensation flow channels are alternately in fluid communication via the communication grooves.

In some embodiments, the heat-absorbing plate further comprises a connecting flow channel allowing two outermost evaporation flow channels in fluid communication.

In some embodiments, the condensation plate and the main body together define a heat exchange chamber, the condensation plate having an inner surface, an outer surface opposite to the inner surface, and a plurality of heat exchange channels recessed from the inner surface, the condensation flow channels being recessed from the outer surface. In some embodiments, the heat exchange flow channels recessed from the inner surface and the condensation flow channels recessed from the outer surface are interleaved to form fin structures. In some embodiments, the interleaved heat exchange flow channels and condensation flow channels form alternating fin segments that increase a heat exchange surface area within the heat exchange chamber.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a perspective view of a water block according to some embodiments of the present disclosure.

FIG. 2 is an exploded view of the water block shown in FIG. 1.

FIG. 3 is an exploded view of the water block shown in FIG. 1, taken from another perspective.

FIG. 4 is a bottom view of the water block shown in FIG. 1.

FIG. 5 is a cross-sectional view taken along line 5–5 of FIG. 4.

FIG. 6 is a cross-sectional view taken along line 6–6 of FIG. 4.

FIG. 7 is a perspective view of a water block according to some embodiments of the present disclosure.

FIG. 8 is an exploded view of the water block shown in FIG. 7.

FIG. 9 is an exploded view of the water block shown in FIG. 7, taken from another perspective.

FIG. 10 is a bottom view of the water block shown in FIG. 7.

FIG. 11 is a cross-sectional view taken along line 11–11 of FIG. 10.

FIG. 12 is a perspective view of a heat-absorbing plate shown in FIG. 8.

FIG. 13 is a cross-sectional view taken along line 13–13 of FIG. 10.

### DETAILED DESCRIPTION OF EMBODIMENTS

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

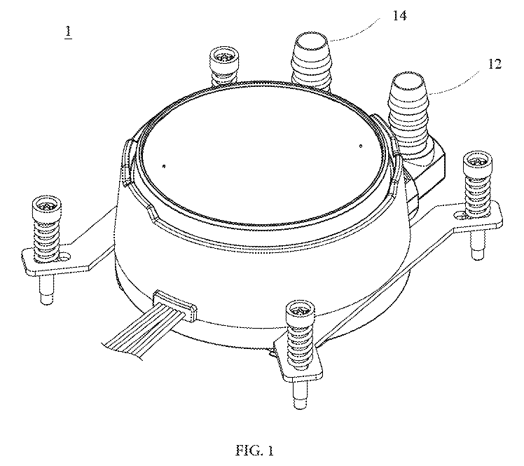

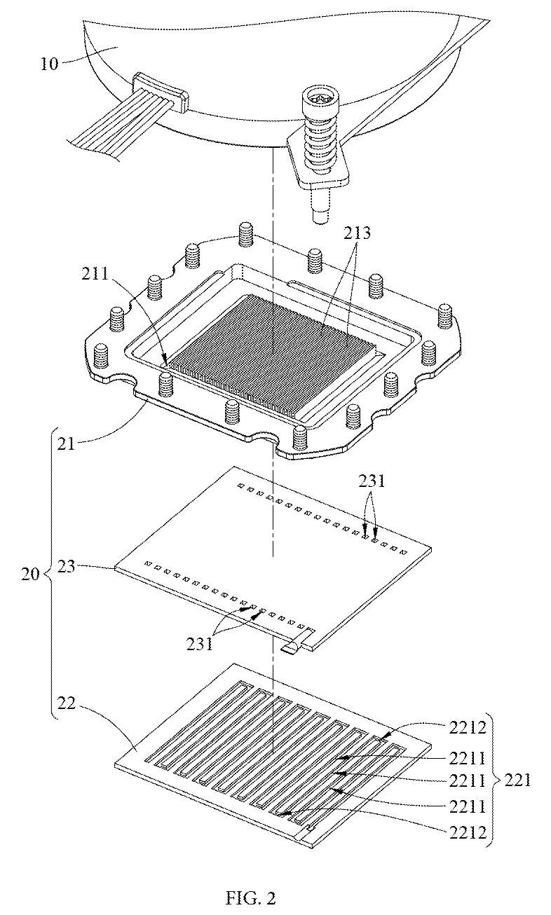

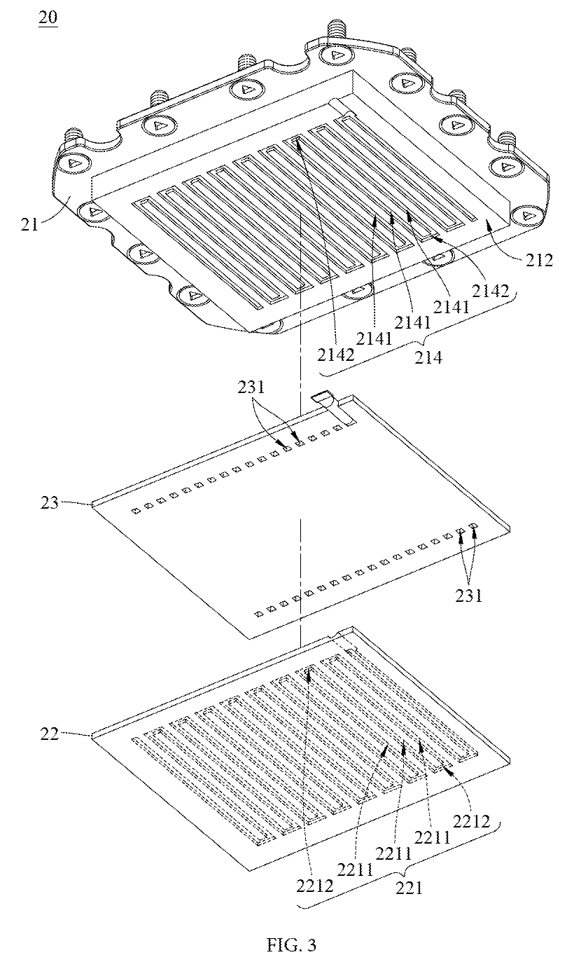

Referring to FIGS. 1-3, FIG. 1 is a perspective view of a water block according to some embodiments of the present invention. FIG. 2 is an exploded view of the water block shown in FIG. 1. FIG. 3 is an exploded view of the water block shown in FIG. 1, taken from another perspective.

In some embodiments, the water block 1 includes a main body 10 and a heat transfer assembly 20. The heat transfer assembly 20 includes a condensation plate 21 and a heat-absorbing plate 22. Additionally, the heat transfer assembly 20 may further include a flow guide plate 23.

In some embodiments, the main body 10 is provided with an inlet connector 12 and an outlet connector 14 for connection to a pipe (not shown). In addition, the main body 10 defines a flow passage that is in fluid communication with the inlet connector 12 and the outlet connector 14, allowing a cooling fluid (not shown) flows into the main body 10 through the inlet connector 12 and flows out of the main body 10 through the outlet connector 14.

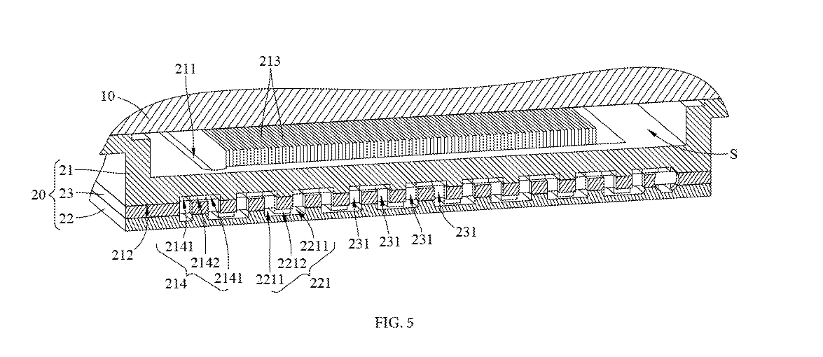

In some embodiments, the condensation plate 21 is secured to the main body 10 by screws. The condensation plate 21 and the main body 10 together define a heat exchange chamber S (shown in FIG. 5). The condensation plate 21 includes an inner surface 211, an outer surface 212 opposite to the inner surface 211, and a plurality of fin structures 213. The inner surface 211 faces the heat exchange chamber S, and the fin structures 213 protrude from the inner surface 211.

In some embodiments, the heat-absorbing plate 22 is coupled with a side of the condensation plate 21 facing away from the main body 10, and the flow guide plate 23 is disposed between the condensation plate 21 and the heat-absorbing plate 22. In some examples, the condensation plate 21, the flow guide plate 23, and the heat-absorbing plate 22 are secured to each other and sealed by welding. The heat-absorbing plate 22 is configured to be thermally coupled to a heat source (not shown), such as a central processing unit, a graphics processing unit or any suitable electronics devices.

In some embodiments, the condensation plate 21 further includes a condensation flow channel 214 recessed from the outer surface 212 of the condensation plate 21. The condensation flow channel 214 is serpentine, including a plurality of first linear segments 2141 and a plurality of first turning segments 2142. The first linear segments 2141 are arranged in parallel, spaced apart, and are successively interconnected by the corresponding first turning segment 2142.

In some embodiments, the heat-absorbing plate 22 includes an evaporation flow channel 221. The evaporation flow channel 221 is serpentine, including a plurality of second linear segments 2211 and a plurality of second turning segments 2212. The second linear segments 2211 are arranged in parallel, spaced apart, and are successively interconnected by the corresponding second turning segment 2212.

In some embodiments, the flow guide plate 23 includes a plurality of communication holes 231, which are arranged along two parallel straight lines on two opposite sides of the flow guide plate 23.

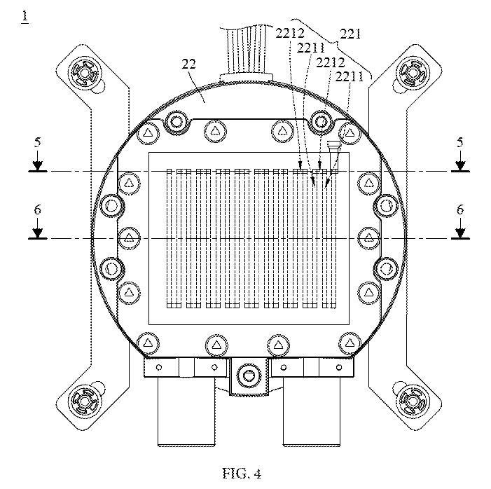

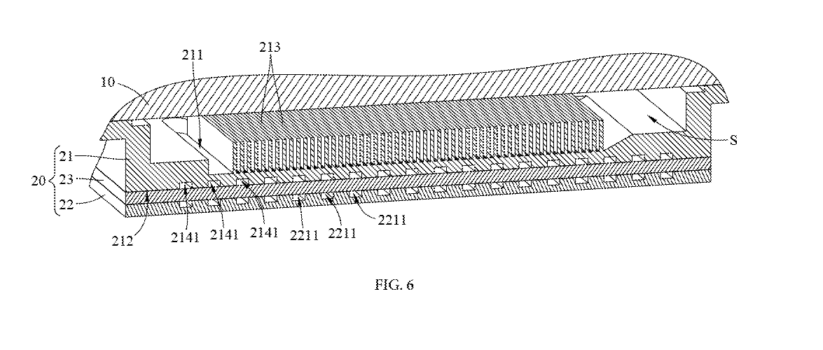

Referring to FIGS. 4-6, FIG. 4 is a bottom view of the water block shown in FIG. 1. FIG. 5 is a cross-sectional view taken along line 5–5 of FIG. 4. FIG. 6 is a cross-sectional view taken along line 6–6 of FIG. 4. As an example illustrated in FIG. 4, each first linear segments 2141 of the condensation flow channel 214 is parallel to a corresponding second linear segments 2211 of the evaporation flow channel 221, and the first linear segments 2141 are respectively aligned with the second linear segments 2211.

In some embodiments, the first turning segments 2142 of the condensation flow channel 214 are respectively disposed opposite to the second turning segments 2212 of the evaporation flow channel 221 and are offset from the second turning segments 2212. In other words, for two adjacent first linear segments 2141 and two corresponding adjacent second linear segments 2211, a first turning segment 2142 connecting the two first linear segments 2141 is disposed opposite to, and offset from, a second turning segment 2212 connecting the two second linear segments 2211. The communication holes 231 of the flow guide plate 23 place the first turning segments 2142 in fluid communication with the second turning segments 2212.

In some embodiments, a flow channel structure collectively formed by the evaporation flow channel 221, the communication holes 231, and the condensation flow channel 214 is similar to an internal flow channel structure of a flat-plate pulsating heat pipe. The flow channel structure is configured to allow a working fluid (not shown) to flow therein. After the heat-absorbing plate 22 absorbs heat from the heat source, the heat drives a liquid-phase working fluid to flow within the evaporation flow channel 221 of the heat-absorbing plate 22 and causes the working fluid to get heated and evaporate. The heated working fluid flows through the communication holes 231 of the flow guide plate 23 into the condensation flow channel 214 of the condensation plate 21. Subsequently, the heated working fluid flowing into the main body 10 exchanges heat with the fin structures 213 of the condensation plate 21 in the heat exchange chamber S, and then exits the heat exchange chamber S to carry the heat away. Simultaneously, after transferring heat to the condensation plate 21, the heated working fluid cools down and condenses back into a liquid phase, and the liquid working fluid flows through the communication holes 231 back into the evaporation flow channel 221 to continue absorbing heat.

According to the embodiments, the condensation plate 21 is coupled with the main body 10, the heat-absorbing plate 22 is coupled with one side of the condensation plate 21 facing away the main body 10, and the evaporation flow channel 221 of the heat-absorbing plate 22 is in fluid communication with the condensation flow channel 214 of the condensation plate 21. With such a configuration, heat generated by the heat source can be uniformly transferred from the heat-absorbing plate 22 to the condensation plate 21 through phase changes of the working fluid within the evaporation flow channel 221. Accordingly, heat exchange efficiency during the working fluid flowing through between the main body 10 and the condensation plate 21 is improved, and the heat dissipation efficiency of the water block 1 is enhanced.

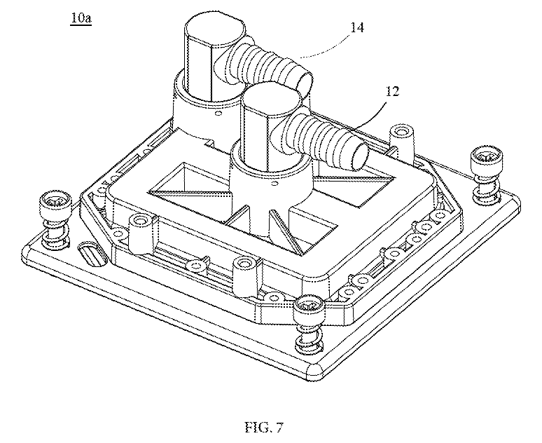

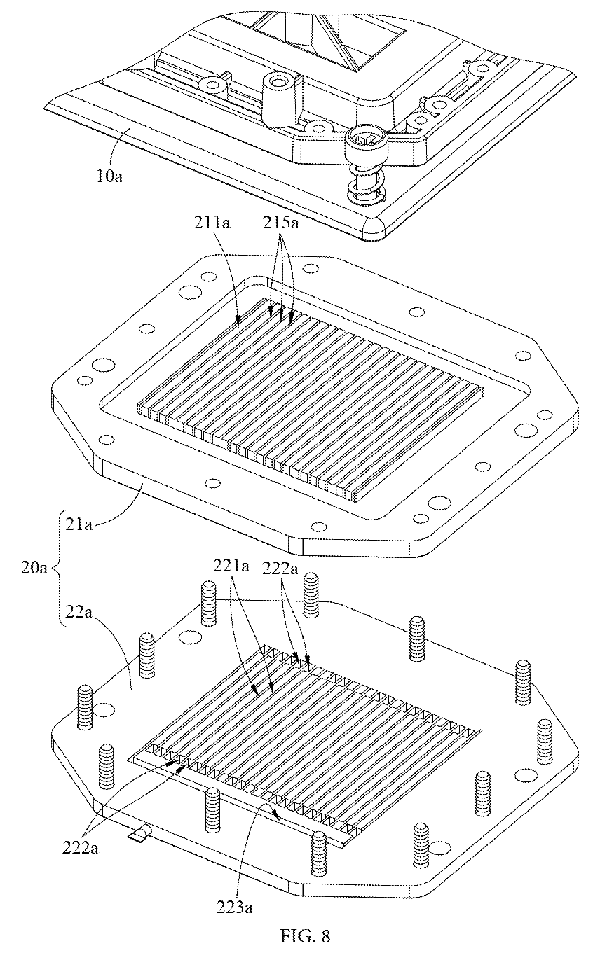

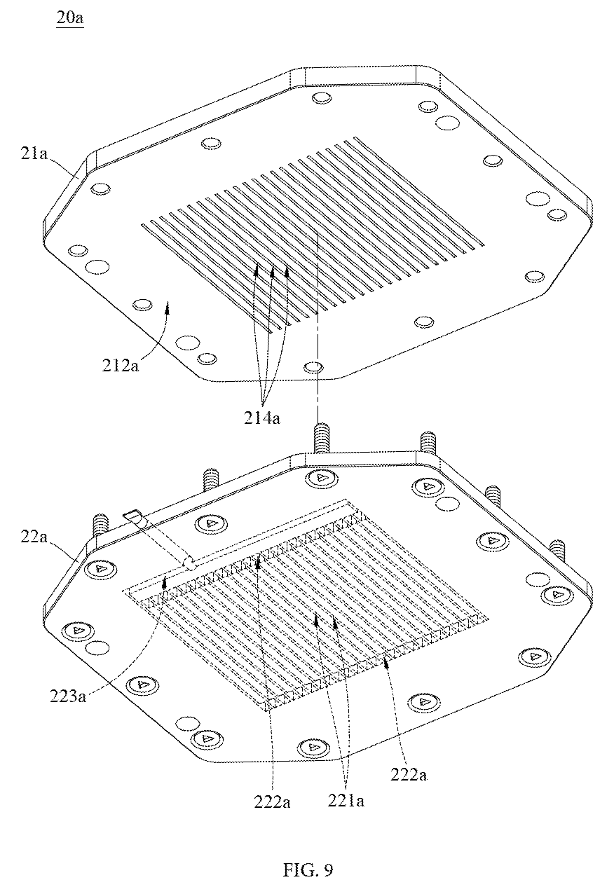

Referring to FIGS. 7-9, FIG. 7 is a perspective view of a water block according to another embodiment of the present disclosure. FIG. 8 is an exploded view of the water block shown in FIG. 7. FIG. 9 is an exploded view of the water block shown in FIG. 7, taken from another perspective.

In some embodiments, the water block 1a includes a main body 10a and a heat transfer assembly 20a. The heat transfer assembly 20a includes a condensation plate 21a and a heat-absorbing plate 22a.

In some embodiments, the main body 10a is provided with an inlet connector 12 and an outlet connector 14 for connection to a pipe (not shown). Additionally, the main body 10a defines a flow passage that is in fluid communication with the inlet connector 12 and the outlet connector 14, allowing a cooling fluid (not shown) flows into the main body 10a through the inlet connector 12 and flows out of the main body 10a through the outlet connector 14.

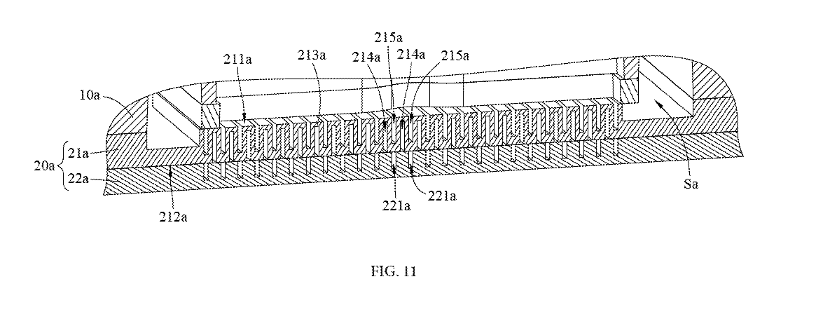

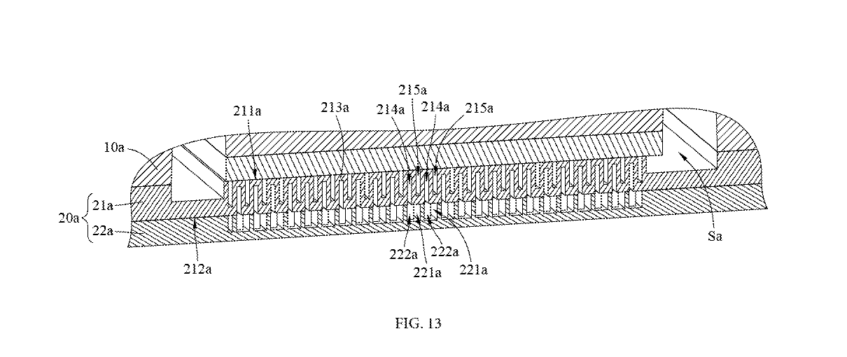

In some embodiments, the condensation plate 21a is mounted to the main body 10a. The condensation plate 21a and the main body 10a together define a heat exchange chamber Sa (shown in FIGS. 11 and 13). The condensation plate 21a includes an inner surface 211a and an outer surface 212a opposite to the inner surface 211a. The inner surface 211a faces the heat exchange chamber Sa. The condensation plate 21a includes a plurality of condensation flow channels 214a. The condensation flow channels 214a are linear flow channels, arranged in parallel, and spaced apart from one another. Additionally, the condensation plate 21a includes a plurality of heat exchange flow channels 215a recessed from the inner surface 211a, the heat exchange flow channels 215a being linear channels arranged in parallel, spaced apart from one another, and interleaved with the condensation flow channels 214a.

In some embodiments, the heat-absorbing plate 22a is coupled with one side of the condensation plate 21a facing away from the main body 10a. The condensation plate 21a and the heat-absorbing plate 22a are, for example, secured to the main body 10a by screws. The heat-absorbing plate 22a is configured to be thermally coupled to a heat source (not shown), such as a central processing unit, a graphics processing unit, or any other suitable electronic devices.

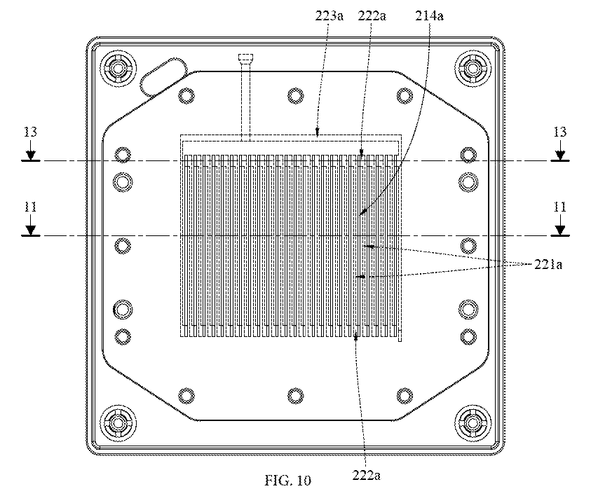

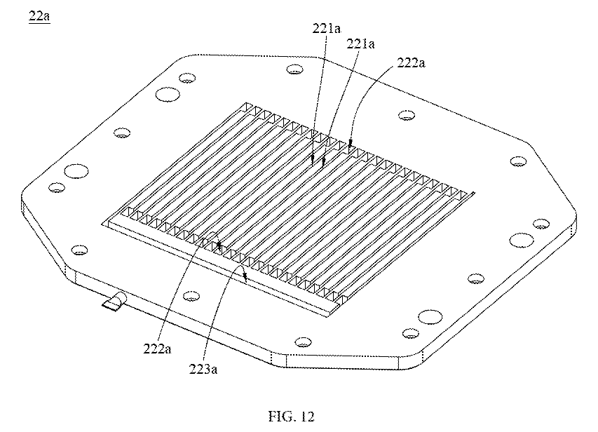

Referring to FIGS. 10-13, FIG. 10 is a bottom view of the water block shown in FIG. 7. FIG. 11 is a cross-sectional view taken along line 11–11 of FIG. 10. FIG. 12 is a perspective view of a heat-absorbing plate shown in FIG. 8. FIG. 13 is a cross-sectional view taken along line 13–13 of FIG. 10.

In some embodiments, the heat-absorbing plate 22a includes a plurality of evaporation flow channels 221a and a plurality of communication grooves 222a. The evaporation flow channels 221a are linear flow channels and arranged in parallel as well as spaced apart from one another. The communication grooves 222a are located at opposite ends of the evaporation flow channels 221a. The condensation flow channels 214a and the evaporation flow channels 221a are interleaved, with the evaporation flow channels 221a in fluid communication with the condensation flow channels 214a via the communication grooves 222a. For example, the evaporation flow channels 221a and the condensation flow channels 214a are alternately placed in fluid communication via the communication grooves 222a.

In some embodiments, the heat-absorbing plate 22a may further include a connecting flow channel 223a, which allows fluid communication between the two outermost evaporation flow channels 221a.

In some embodiments, a flow channel structure collectively formed by the evaporation flow channels 221a, the communication grooves 222a, and the condensation flow channels 214a is similar to an internal flow channel structure of a flat-plate pulsating heat pipe. The flow channel structure is configured to allow a working fluid (not shown) to flow therein. After the heat-absorbing plate 22a absorbs heat from the heat source, the heat drives a liquid-phase working fluid to flow within the evaporation flow channels 221a of the heat-absorbing plate 22a and causes the working fluid to get heated and evaporate. The heated working fluid flows through the communication grooves 222a of the heat-absorbing plate 22a into the condensation flow channels 214a of the condensation plate 21a. Subsequently, the heated working fluid flowing into the main body 10a exchanges heat with the fin structures 213a of the condensation plate 21a in the heat exchange chamber Sa, and then exits the heat exchange chamber Sa to carry the heat away. Simultaneously, after transferring heat to the condensation plate 21a, the heated working fluid cools down and condenses back into a liquid phase, and the liquid-phase working fluid flows through the communication grooves 222a back into the evaporation flow channels 221a to continue absorbing heat.

According to the embodiments, the condensation plate 21a is coupled with the main body 10a, the heat-absorbing plate 22a is coupled with one side of the condensation plate 21a facing away from the main body 10a, and the evaporation flow channels 221a of the heat-absorbing plate 22a are in fluid communication with the condensation flow channels 214a of the condensation plate 21a. With such a configuration, heat generated by the heat source is uniformly transferred from the heat-absorbing plate 22a to the condensation plate 21a through phase changes of a working fluid within the evaporation flow channels 221a. Accordingly, heat exchange efficiency during the cooling fluid flowing through between the main body 10a and the condensation plate 21a is improved, and the heat dissipation efficiency of the water block 1a is enhanced.

Additionally, heat exchange flow channels 215a recessed from the inner surface 211a of the condensation plate 21a and the condensation flow channels 214a recessed from the outer surface 212a of the condensation plate 21a are interleaved to form a louver-type fin structure 213a. Such a configuration increases the heat exchange area between the cooling fluid and the condensation plate 21a, hence improving the heat dissipation efficiency of the water block 1a.

According to the embodiments, the evaporation flow channels 221a of the heat-absorbing plate 22a are in fluid communication with the condensation flow channels 214a of the condensation plate 21a via the communication grooves 222a of the heat-absorbing plate 22a. However, the embodiment is not limited thereto. In other embodiments, the heat-absorbing plate may omit the communication grooves, and the condensation plate may instead include communication grooves, such that the evaporation flow channels of the heat-absorbing plate could be in fluid communication with the condensation flow channels of the condensation plate via the communication grooves of the condensation plate.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A water block for a liquid cooling device, the water block comprising:
a main body; and
a heat transfer assembly, comprising:
a condensation plate coupled with the main body, the condensation plate having a condensation flow channel; and
a heat-absorbing plate coupled with one side of the condensation plate facing away from the main body, the heat-absorbing plate having an evaporation flow channel; and
a flow guide plate disposed between the condensation plate and the heat-absorbing plate, the flow guide plate having a plurality of communication holes, the evaporation flow channel being in fluid communication with the condensation flow channel through the communication holes.

2. The water block of claim 1, wherein the condensation flow channel is serpentine.

3. The water block of claim 1, wherein the evaporation flow channel is serpentine.

4. The water block of claim 1, wherein the condensation flow channel includes a plurality of first linear segments and a plurality of first turning segments, and the evaporation flow channel includes a plurality of second linear segments and a plurality of second turning segments.

5. The water block of claim 4, wherein the first linear segments are parallel and spaced apart from one another and successively interconnected by a corresponding first turning segment.

6. The water block of claim 4, wherein the second linear segments are parallel and spaced apart from one another and successively interconnected by a corresponding second turning segment.

7. The water block of claim 4, wherein the first linear segments are aligned with the second linear segments.

8. The water block of claim 4, wherein the communication holes are arranged in two parallel rows on opposite sides of the flow guide plate.

9. The water block of claim 4, wherein the communication holes connect the first turning segments to the second turning segments.

10. The water block of claim 1, wherein the condensation plate and the main body together define a heat exchange chamber, the condensation plate having an inner surface, an outer surface opposite to the inner surface, and a plurality of fin structures protruding from the inner surface, the condensation flow channel being recessed from the outer surface.

11. The water block of claim 1, wherein the evaporation flow channel, the communication holes, and the condensation flow channel collectively form a closed flow path containing a working fluid that undergoes phase changes between liquid and vapor states.

12. The water block of claim 1, wherein the condensation plate and the heat-absorbing plate are coupled together along a peripheral region to define a closed internal flow space for circulation of a working fluid.

13. A water block for a liquid cooling device, the water block comprising:
a main body; and
a heat transfer assembly, comprising:
a condensation plate coupled with the main body, the condensation plate having a plurality of linear condensation flow channels, the condensation flow channels being parallel and spaced apart; and
a heat-absorbing plate coupled with one side of the condensation plate facing away from the main body, the heat-absorbing plate having a plurality of linear evaporation flow channels, the evaporation flow channels being parallel and spaced apart, the evaporation flow channels being in fluid communication with the condensation flow channels.

14. The water block of claim 13, wherein the condensation flow channels and the evaporation flow channels are interleaved.

15. The water block of claim 13, wherein the heat-absorbing plate further comprises a plurality of communication grooves located at opposite ends of the evaporation flow channels, the evaporation flow channels being in fluid communication with the condensation flow channels via the communication grooves.

16. The water block of claim 15, wherein the evaporation flow channels and the condensation flow channels are alternately in fluid communication via the communication grooves.

17. The water block of claim 13, wherein the heat-absorbing plate further comprises a connecting flow channel allowing two outermost evaporation flow channels in fluid communication.

18. The water block of claim 13, wherein the condensation plate and the main body together define a heat exchange chamber, the condensation plate having an inner surface, an outer surface opposite to the inner surface, and a plurality of heat exchange channels recessed from the inner surface, the condensation flow channels being recessed from the outer surface.

19. The water block of claim 18, wherein the heat exchange flow channels recessed from the inner surface and the condensation flow channels recessed from the outer surface are interleaved to form fin structures.

20. The water block of claim 19, wherein the interleaved heat exchange flow channels and condensation flow channels form alternating fin segments that increase a heat exchange surface area within the heat exchange chamber.
